(19) United States
(12) Patent Application Publication
(10) Pub. No.: US 2012/0317798 A1
(43) Pub. Date: Dec. 20, 2012

(54) COMPONENT MOUNTING DEVICE

(75) Inventors: Yoshiyuki Kitagawa, Yamanashi (JP); Mitsumasa Mino, Yamanashi (JP); Kenji Mori, Yamanashi (JP)

(73) Assignee: PANASONIC CORPORATION, Osaka (JP)

(21) Appl. No.: 13/579,393

(22) PCT Filed: Dec. 13, 2011
(86) PCT No.: PCT/JP2011/006957

§ 371 Date: Aug. 16, 2012

(30) Foreign Application Priority Data
Jan. 7, 2011 (JP) 2011-001744

(51) Int. Cl. H05K 13/00

(52) U.S. Cl. 29/739

(57) ABSTRACT

An electric power supplying circuit (52) which supplies electric power to a front mounting head moving mechanism driving part (45a) and a rear mounting head moving mechanism driving part (45b) has a first electric power supply interrupting part (53) which, when a front carriage connection switch (71a) is operated when a front carriage (19a) that is attached to a base (11) is detached from the base (11), only interrupts the electric power supply to the front mounting head moving mechanism driving part (45a), and a second electric power supply interrupting part (54) which, when a rear carriage connection switch (71b) is operated when a rear carriage (19b) that is attached to the base (11) is detached from the base (11), only interrupts the electric power supply to the rear mounting head moving mechanism driving part (45b).

### TECHNICAL FIELD

The present invention relates to a component mounting device which mounts a component picked up by an mounting head on a board positioned by a conveyor.

### BACKGROUND ART

A component mounting device includes a conveyor which is arranged on a base and conveys and positions a board, a parts feeder which is attached to the base, and an mounting head which moves relative to the board which is positioned by the conveyor, picks up a component supplied from the parts feeder and mounts the component on the board which is positioned by the conveyor.

In the component mounting device, the parts feeder is provided on a carriage which is attached to the base. When the carriage is detached from the base in order to change the parts feeder due to the exhaustion of components, it is necessary to stop component mounting operations performed by the mounting head. Besides that, in case that the hand of an operator is inserted from the part of the base where the carriage is detached, it is unfavorable in safety that the mounting head is acting. Thus, it is preferred that the power supply to the driving part of the moving mechanism of the mounting head is interrupted. Further, even when a check door which is a part of a cover member that covers the base is opened by an operator or an emergency stop operating part is operated by an operator, the power supply to the above driving part is interrupted in view of securing the safety of the operator in operation (for example, a patent document 1).

### RELATED ART DOCUMENT

### Patent Document

Patent document 1: Japan Patent Publication No. 2008-60437

### SUMMARY OF THE INVENTION

### Problem to be Solved by the Invention

A dual lane type component mounting device, which includes two conveyors and two mounting heads, can perform mounting operations in a way that one mounting head performs component mounting operations on the board positioned by one conveyor and the other mounting head performs component mounting operations on the board positioned by the other conveyor. That is, component mounting operations (independent mounting operations) can be performed in a way that the two mounting heads independently perform component mounting operations respectively on two boards which are positioned by the two conveyors. If the above structure is applied to the dual lane type component mounting device, when one carriage is detached from the base in order to change the parts feeder due to the exhaustion of components, component mounting operations cannot be performed since not only the power supply to the mounting head at the side of detaching the carriage, but also the power supply to the mounting head at the other side where it is not feared that the hand of the operator is inserted from the part of the base where the carriage is detached, are interrupted. Thus, there is a problem that the operation efficiency may decrease remarkably.

The invention is intended to provide a component mounting device so that in the dual lane type component mounting device which performs independent mounting operations, while the decrease of the operation efficiency is prevented, the safety of an operator can be secured.

### Solution for Solving the Problem

A component mounting device of this invention comprises a first conveyor and a second conveyor which are arranged so as to be extended in parallel on a base, and which convey and position boards, respectively, a first parts feeder which is attached to the first conveyor side of the base, a second parts feeder which is attached to the second conveyor side of the base, a first mounting head which moves relative to the board positioned by the first conveyor, picks up a component supplied from the first parts feeder and mounts the component on the board positioned by the first conveyor, a second mounting head which moves relative to the board positioned by the second conveyor, picks up a component supplied from the second parts feeder and mounts the component on the board positioned by the second conveyor, a first mounting head moving mechanism driving part which drives a first mounting head moving mechanism that is the moving mechanism of the first mounting head, a second mounting head moving mechanism driving part which drives a second mounting head moving mechanism that is the moving mechanism of the second mounting head, and an electric power supplying circuit which supplies electric power to the first mounting head moving mechanism driving part and the second mounting head moving mechanism driving part, wherein the electric power supplying circuit has a first electric power supply interrupting unit which, when a first operating part is operated, only interrupts the electric power supply to the first mounting head moving mechanism driving part among the electric power supplies of the electric power supplying circuit to the first mounting head moving mechanism driving part and the second mounting head moving mechanism driving part, and a second electric power supply interrupting unit which, when a second operating part is operated, only interrupts the electric power supply to the second mounting head moving mechanism driving part among the electric power supplies of the electric power supplying circuit to the first mounting head moving mechanism driving part and the second mounting head moving mechanism driving part.

In the component mounting device of this invention, wherein the first parts feeder is provided on a first carriage which is attached to the first conveyor side of the base while the second parts feeder is provided on a second carriage which is attached to the second conveyor side of the base, and the first operating part is operated when the first carriage which is attached to the base is detached from the base, while the second operating part is operated when the second carriage which is attached the base is detached from the base.

In the component mounting device of this invention, the electric power supplying circuit has a third electric power supply interrupting unit which, when a third operating part is operated, interrupts both the electric power supply of the electric power supplying circuit to the first mounting head moving mechanism driving part and the electric power supply of the electric power supplying circuit to the second mounting head moving mechanism driving part.

In the component mounting device of this invention, wherein the third operating part is operated when a part of a cover member which covers the base is opened or an emergency stop operating part is operated.

### Effects of the Invention

In the present invention, the power supplying circuit which performs power supplies to the first mounting head moving mechanism driving part and the second mounting head moving mechanism driving part has the first electric power supply interrupting unit which only interrupts the power supply to the first mounting head moving mechanism driving part when the first operating part is operated, and the second electric power supply interrupting unit which only interrupts the power supply to the second mounting head moving mechanism driving part when the second operating part is operated. Therefore, if the first operating part is operated when one carriage (the first carriage) is detached from the base and the second operating part is operated when the other carriage (the second carriage) is detached from the base, when one carriage is detached from the base in order to change the parts feeder due to the exhaustion of components, the component mounting operations of the conveyor and the mounting head at the side of detaching the carriage are stopped, but the component mounting operations of the conveyor and the mounting head at the other side are continued. Therefore, according to the present invention, while the decrease of the operation efficiency is prevented, the safety of an operator can be secured.

### BRIEF DESCRIPTION OF THE FIGURES

FIG. 1 is a top view of a component mounting device in one embodiment of the present invention.

FIG. 2 is a side view of the component mounting device in the embodiment of the present invention.

FIG. 3 is a block diagram which shows a control system of the component mounting device in the embodiment of the present invention.

FIG. 4 is a block diagram which shows a power supply system of the component mounting device in the embodiment of the present invention.

### EMBODIMENTS OF THE INVENTION

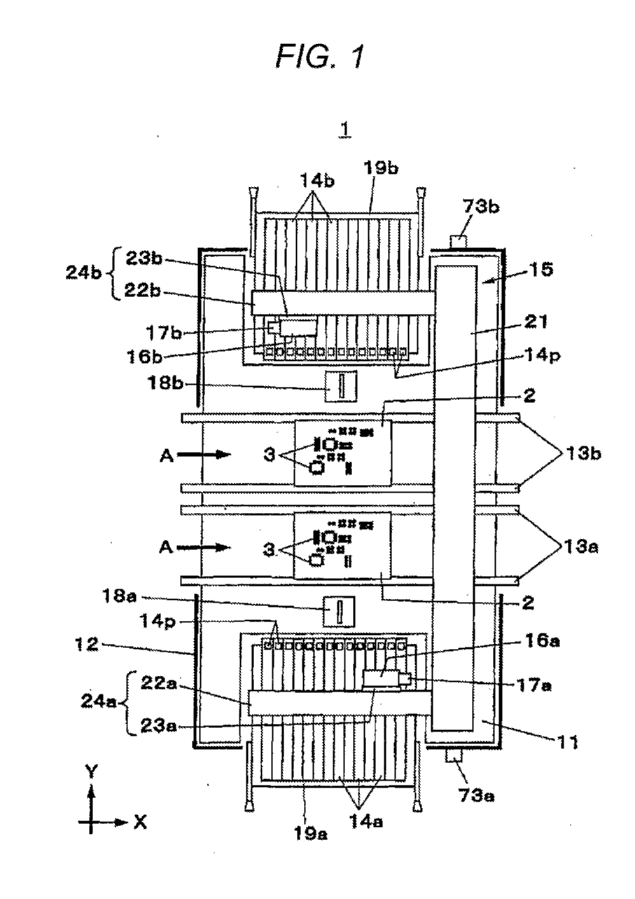

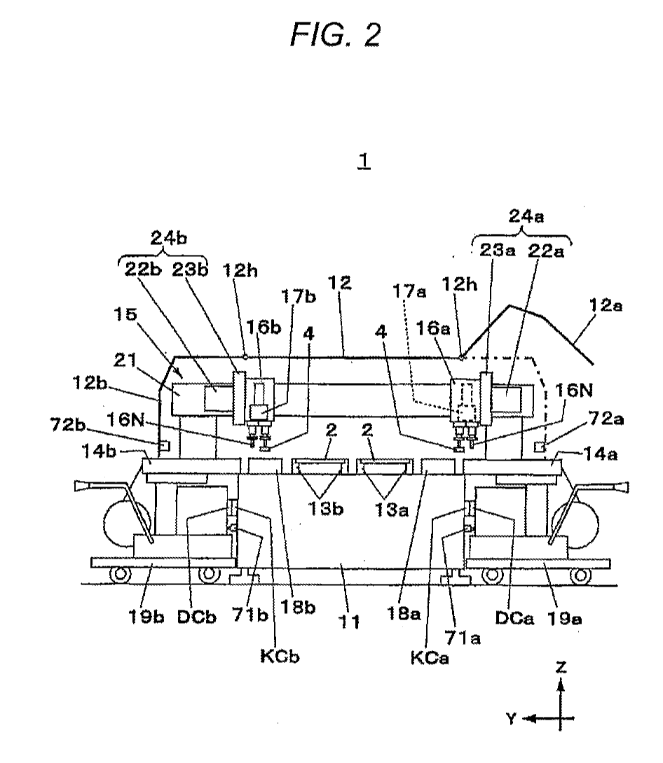

Below, an embodiment of the invention is described with reference to the figures. A component mounting device 1 shown in FIGS. 1 and 2 is a device which repeatedly performs a series of steps which include importing and positioning a board 2, mounting a component(electronic component) 4 to electrodes 3 on the positioned board 2, and exporting the board 2 on which the component 4 is mounted. In the present embodiment, the direction of conveying the board 2 (arrow A show in FIG. 1) in the component mounting device 1 is assumed as an X axis direction, the direction in the horizontal plane perpendicular to the X axis direction is assumed as a Y axis direction, and the up and down direction is assumed as a Z axis direction.

In FIGS. 1 and 2, besides a base 11 and a cover member 12 which covers the base 11, the component mounting device 1 includes a front conveyor 13a (a first conveyor) and a rear conveyor 13b (a second conveyor) which are provided to extend in the X axis direction over the board 2, a front parts feeder 14a (a first parts feeder) and a rear parts feeder 14b (a second parts feeder) which perform the supply of components 4, a head moving robot 15 which is provided on the base 11, a front mounting head 16a (a first mounting head) and a rear mounting head 16b (a second mounting head) which are moved by the head moving robot 15, a front board camera 17a which is provided at the front mounting head 16a and a rear board camera 17b which is provided at the rear mounting head 16b, and a front component camera 18a and a rear component camera 18b which are provided on the base 11.

The front conveyor 13a and the rear conveyor 13b are arranged so as to be extended in parallel on the base 11, and convey and position boards 2 in the X axis direction, respectively.

There are a plurality of the front parts feeders 14a that are arranged on a front carriage 19a (a first carriage) which is attached to the end of the base to 11 at the side of the front conveyor 13a (front end), and there are a plurality of the rear parts feeders 14b that are arranged on a rear carriage 19b (a second carriage) which is attached to the end of the base 11 at the side of the rear conveyor 13b (rear end). The front parts feeders 14a and the rear parts feeders 14b continuously supply components 4 to component takeout ports 14p which are provided at the ends at the central part of the base 11, respectively.

In FIGS. 1 and 2, the head moving robot 15 includes a Y axis table 21 which is provided in the Y axis direction over the front conveyor 13a and the rear conveyor 13b, a front X axis table 22a and a rear X axis table 22b which are provided on the Y axis table 21 to be movable in the Y axis direction and extend in the X axis direction, and a front moving stage 23a which is provided on the front X axis table 22a to be movable in the X axis direction and a rear moving stage 23b which is provided on the rear X axis table 22b to be movable in the X axis direction. The front mounting head 16a is attached to the front moving stage 23a, and the rear mounting head 16b is attached to the rear moving stage 23b. The front X axis table 22a and the front moving stage 23a form a front mounting head moving mechanism 24a which is a moving mechanism of the front mounting head 16a, and the rear X axis table 22b and the rear moving stage 23b form a rear mounting head moving mechanism 24b which is a moving mechanism of the rear mounting head 16b.

In FIG. 2, a plurality of adsorbing nozzles 16N are provided in the front mounting head 16a and the rear mounting head 16b, respectively, and each of the adsorbing nozzles 16N is movable up and down and rotatable around a up and down axis (the Z axis). The front mounting head 16a moves relative to the board 2 which is positioned by the front conveyor 13a, adsorbs (picks up) a component 4 which is supplied from the front parts feeder 14a and mounts the component 4 on the board 2 which is positioned by the front conveyor 13a. The rear mounting head 16b moves relative to the board 2 which is positioned by the rear conveyor 13b, adsorbs a component 4 which is supplied from the rear parts feeder 14b and mounts the component 4 on the board 2 which is positioned by the rear conveyor 13b.

In FIGS. 1 and 2, the front board cameras 17a and the rear board camera 17b are respectively attached to the front mounting head 16a and the rear mounting head 16b with an imaging field of vision directed downward. Further, the front component camera 18a and the rear component camera 18b are provided respectively at positions that sandwich the front conveyor 13a and the rear conveyor 13b on the base 11 with an imaging field of vision directed upward, respectively.

In FIG. 2, a front check door 12a which is a part of the cover member 12 is provided at the front of the cover member 12, and a rear check door 12b which is a part of the cover member 12 is provided at the rear of the cover member 12. The front check door 12a and the rear check door 12b can be opened and closed in the up and down direction around hinges 12h which are respectively provided at the cover member 12. An operator (not shown in the figure) can access the front conveyor 13a and the front mounting head 16a when the front check door 12a is opened upwards, and can access the rear conveyor 13b and the rear mounting head 16b when the rear check door 12b is opened upwards.

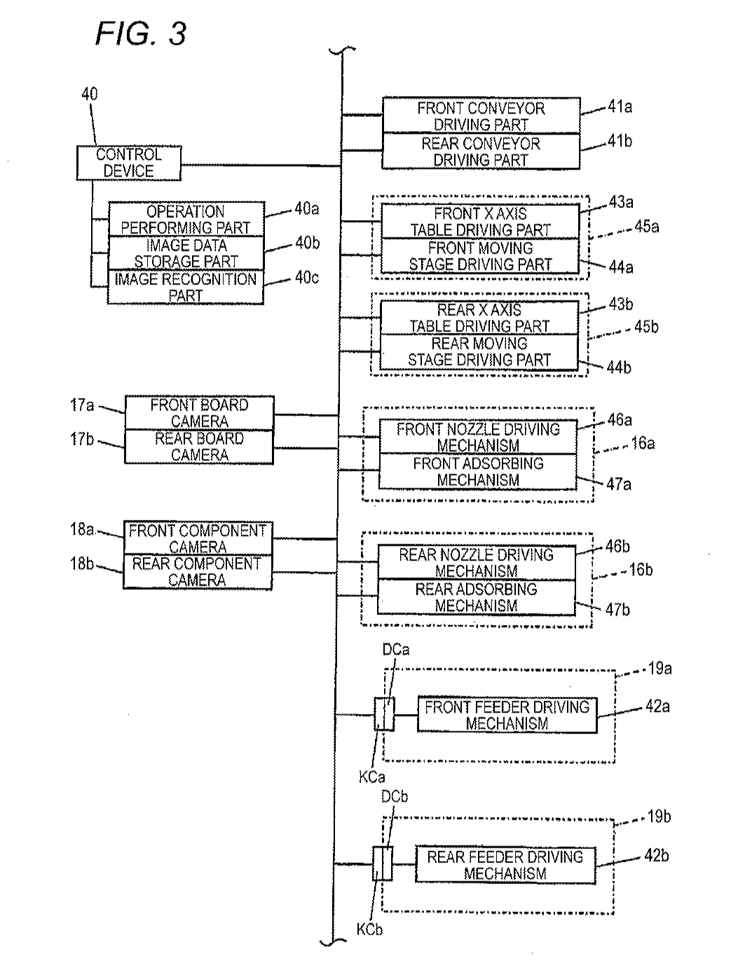

In the component mounting device 1, an operation performing part 40a to of a control device 40 (FIG. 3), which the component mounting device 1 includes, controls the operation of a front conveyor driving part 41a (FIG. 3) which includes an actuator such as a motor which is not shown in the figure so that the board 2 is conveyed and positioned to the predetermined operation position (the position shown in FIG. 1) by the front conveyor 13a. The operation performing part 40a of the control device 40 controls the operation of a rear conveyor driving part 41b (FIG. 3) which includes an actuator such as a motor which is not shown in the figure so that the board 2 is conveyed and positioned to the predetermined operation position (the position shown in FIG. 1) by the rear conveyor 13b.

In the present embodiment, the front conveyor driving part 41a functions as a first conveyor driving part that drives the front conveyor 13a which is the first conveyor, and the rear conveyor driving part 41b functions as a second conveyor driving part that drives the rear conveyor 13b which is the second conveyor.

The operation performing part 40a of the control device 40 controls the operation of a front feeder driving mechanism 42a (FIG. 3) which includes an actuator which is not shown in the figure so that the component 4 is supplied to the component takeout port 14p by the front parts feeder 14a. The operation performing part 40a of the control device 40 controls the operation of a rear feeder driving mechanism 42b (FIG. 3) which includes an actuator which is not shown in the figure so that the component 4 is supplied to the component takeout port 14p by the rear parts feeder 14b.

For the front parts feeder 14a, when the front carriage 19a is attached to the front end of the base 11, a connector DCa at the side of the front carriage 19a is fitted to and connected with a connector KCa at the side of the base 11 so that the operation of the front parts feeder 14a can be controlled by the control device 40 (FIG. 2). For the rear parts feeder 14b, when the rear carriage 19b is attached to the rear end of the base 11, a connector DCb at the side of the rear carriage 19b is fitted to and connected with a connector KCb at the side of the base 11 so that the operation of the rear parts feeder 14b can be controlled by the control device 40 (FIG. 2).

The operation performing part 40a of the control device 40 makes the front mounting head moving mechanism 24a to operate by controlling the operation of a front mounting head moving mechanism driving part 45a (FIG. 3) which includes a front X axis table driving part 43a (FIG. 3) which includes an actuator such as a motor which is not shown in the figure to make the front X axis table 22a to move in the Y axis direction relative to the Y axis table 21 and a front moving stage driving part 44a (FIG. 3) which makes the front moving stage 23a to move in the X axis direction relative to the front X axis table 22a, so that the front mounting head 16a moves in directions of a horizontal plane.

The operation performing part 40a of the control device 40 makes the rear mounting head moving mechanism 24b to operate by controlling the operation of a rear mounting head moving mechanism driving part 45b (FIG. 3) which includes a rear X axis table driving part 43b (FIG. 3) which includes an actuator such as a motor which is not shown in the figure to make the rear X axis table 22b to move in the Y axis direction relative to the V axis table 21 and a rear moving stage driving part 44b (FIG. 3) which makes the rear moving stage 23b to move in the X axis direction relative to the rear X axis table 22b, so that the rear mounting head 16b moves in directions of a horizontal plane.

Thus,the front mounting head moving mechanism driving part 45a of the head moving robot 15 functions as a first mounting head moving mechanism driving part which drives the front mounting head moving mechanism 24a (the first mounting head moving mechanism) which is the moving mechanism of the front mounting head 16a, and the rear mounting head moving mechanism driving part 45b of the head moving robot 15 functions as a second mounting head moving mechanism driving part which drives the rear mounting head moving mechanism 24b (the second mounting head moving mechanism) which is the moving mechanism of the rear mounting head 16b.

The operation performing part 40a of the control device 40 controls the operation of a front nozzle driving mechanism 46a (FIG. 3) which includes an actuator which is not shown in the figure so that the adsorbing nozzles 16N which the front mounting head 16a includes move up and down and rotate around the up and down axis relative to the front mounting head 16a. The operation performing part 40a of the control device 40 controls the operation of a rear nozzle driving mechanism 46b (FIG. 3) which includes an actuator which is not shown in the figure so that the adsorbing nozzles 16N which the rear mounting head 16b includes move up and down and rotate around the up and down axis relative to the rear mounting head 16b.

The operation performing part 40a of the control device 40 controls the operation of a front adsorbing mechanism 47a (FIG. 3) which includes an actuator which is not shown in the figure to supply a vacuum pressure to the absorbing nozzles 16N and release the supply of the vacuum pressure so that the components 4 are adsorbed (picked up) and desorbed (separated) by the adsorbing nozzles 16N of the front mounting head 16a. The operation performing part 40a of the control device 40 controls the operation of a rear adsorbing mechanism 47b (FIG. 3) which includes an actuator which is not shown in the figure to supply a vacuum pressure to the absorbing nozzles 16N and release the supply of the vacuum pressure so that the components 4 are adsorbed and desorbed by the adsorbing nozzles 16N of the rear mounting head 16b.

The operation performing part 40a of the control device 40 controls the imaging operations of the front board camera 17a and the rear board camera 17b and the imaging operations of the front component camera 18a and the rear component camera 18b (FIG. 3). After image data obtained by the imaging operations of the front board camera 17a and the rear board camera 17b and image data obtained by the imaging operations of the front component camera 18a and the rear component camera 18b are stored in an image data storage part 40b of the control device 40 (FIG. 3), the image data are processed to be recognized in an image recognition part 40c of the control device 40 (FIG. 3).

In the component mounting device 1 of the present embodiment, as described above, the component 4 supplied from the front parts feeder 14a is picked up and mounted by the front mounting head 16a on the board 2 positioned by the front conveyor 13a, and the component 4 supplied from the rear parts feeder 14b is picked up and mounted by the rear mounting head 16b on the board 2 positioned by the rear conveyor 13b. Below, the front conveyor 13a, the front parts feeder 14a and the front mounting head 16a are referred as a “front operating part”, and the rear conveyor 13b, the rear parts feeder 14b and the rear mounting head 16b are referred to as a “rear operating part”. The component mounting operation of mounting the component 4 on the board 2 performed by the front operating part is referred to as a “mounting operation of the front operating part”, and the component mounting operation of mounting the component 4 on the board 2 performed by the rear operating part is referred to as a “mounting operation of the rear operating part”.

In the mounting operation of the front operating part, after the board 2, which has been cast from another device (for example, a solder printing machine) placed at the upstream of the component mounting device 1, is imported and positioned at a predetermined operation position by the front conveyor 13a, the operation performing part 40a of the control device 40 makes the front board camera 17a (the front mounting head 16a) to move to be above the board 2 by actuating the head moving robot 15, and makes the front board camera 17a to image a board mark (not shown in the figure) that is provided on the board 2. After the front board camera 17a images the board mark, the image recognition part 40c of the control device 40 performs image recognition based on the obtained image data.

After the image recognition of the board mark is performed by the image recognition part 40c, the operation performing part 40a of the control device 40 calculates a positional deviation of the board 2 from the normal operation position based on the image recognition result.

After the positional deviation of the board 2 is calculated, the operation performing part 40a of the control device 40 makes the front mounting head 16a to move to be above the front parts feeder 14a by actuating the head moving robot 15, and makes the adsorbing nozzle 16N to touch the component 4 which is supplied at the component takeout port 14p of the front parts feeder 14a. At the same time, the operation performing part 40a of the control device 40 controls the operation of the front adsorbing mechanism 47a so that a vacuum pressure is supplied to the adsorbing nozzle 16N and the component 4 is adsorbed (picked up) by the adsorbing nozzle 16N.

After the component 4 is adsorbed by the adsorbing nozzle 16N, the operation performing part 40a of the control device 40 makes the front mounting head 16a to move so that the adsorbed component 4 passes over the front component camera 18a, and makes the front component camera 18a to image the component 4 from below. After the front component camera 18a images the component 4, the image recognition part 40c of the control device 40 performs image recognition based on the obtained image data.

After the image recognition of the component 4 is performed by the image recognition part 40c of the control device 40, the operation performing part 40a of the control device 40 detects whether there is an abnormality (deformation or defect) of the component 4 based on the obtained image recognition result, and calculates the adsorption deviation of the component 4 relative to the adsorbing nozzle 16N.

After the component 4 is detected and the adsorption deviation of the component 4 is calculated, the operation performing part 40a of the control device 40 makes the front mounting head 16a to move to be above the board 2, makes the component 4 which is adsorbed by the adsorbing nozzle 16N to contact to a target mounting site (solder is printed on an electrode 3 at the target mounting site by a solder printing machine arranged at the upstream of the component mounting device 1) on the board 2 by controlling the operation of the front nozzle driving mechanism 46a, releases the supply of the vacuum pressure to the adsorbing nozzle 16N by controlling the operation of the front adsorbing mechanism 47a, and mounts the component 4 on the board 2.

When the component 4 is mounted on the board 2, the operation performing part 40a of the control device 40 performs position revision (including rotary revision) of the adsorbing nozzle 16N relative to the board 2 (so that the position deviation and the adsorption deviation are cancelled) based on the calculated position deviation of the board 2 and the adsorption deviation of the component 4 relative to the adsorbing nozzle 16N.

The operation performing part 40a of the control device 40 repeats the steps from picking up the component 4 to mounting the component 4 on the board 2 until all components 4 that should be mounted on the board 2 have been mounted. After all components 4 that should be mounted on the board 2 have been mounted on the board 2, the operation performing part 40a of the control device 40 makes the front conveyor 13a to be actuated so that the board 2 is exported to another device (for example, a post-mounting inspection machine) which is arranged at the downstream of the component mounting device 1.

The procedures of performing the mounting operation of the rear operating part are exactly the same as the procedures of performing the mounting operation of the front operating part. The mounting operation of the front operating part and the mounting operation of the rear operating part are performed independently from each other.

In the middle of the above component mounting operation, an operator may perform an operation of changing a parts feeder (the front parts feeder 14a or the rear parts feeder 14b) due to the exhaustion of components or an operation of checking a conveyor (the front conveyor 13a or the rear conveyor 13b) or an mounting head (the front mounting head 16a or the rear mounting head 16b) by opening a check door (the front check door 12a or the rear check door 12b). However, with the component mounting device 1 in the present embodiment, the safety of the operator is secured without decreasing the operation efficiency in the above operation of changing the parts feeder. Below, the structure of the component mounting device 1 is described.

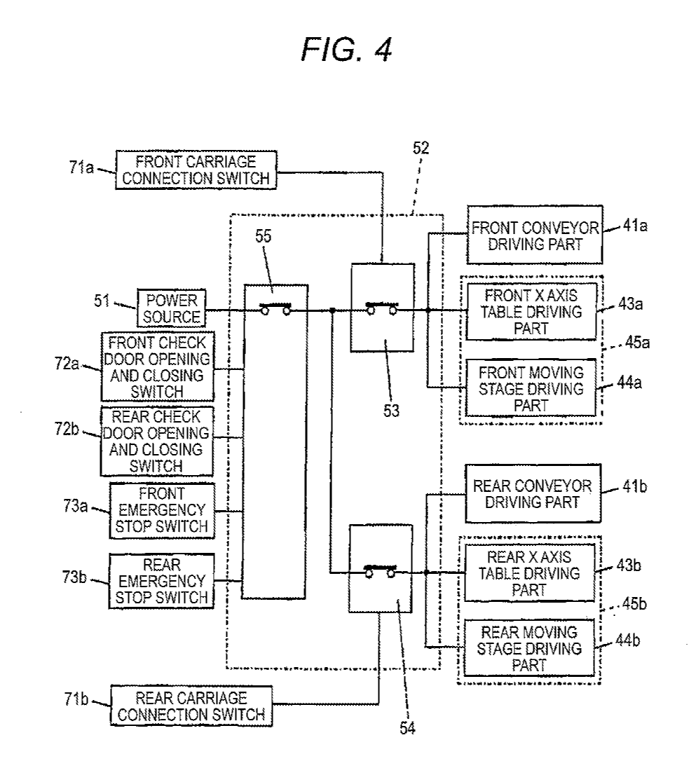

In FIG. 4, the component mounting device 1 includes a power source 51 and an electric power supplying circuit 52. The electric power supplying circuit 52 supplies electric power from the power source 51 to the front conveyor driving part 41a, the front mounting head moving mechanism driving part 45a, the rear conveyor driving part 41b and the rear mounting head moving mechanism driving part 45b.

In FIG. 4, the electric power supplying circuit 52 has a first electric power supply interrupting part 53 (a first electric power supply interrupting unit), a second electric power supply interrupting part 54 (a second electric power supply interrupting unit) and a third electric power supply interrupting part 55 (a third electric power supply interrupting unit).

In FIG. 4, the first electric power supply interrupting part 53 functions as a first electric power supply interrupting unit which, when a front carriage connection switch 71a which is a first operating part is operated, only interrupts the electric power supply to the front mounting head moving mechanism driving part 45a among the electric power supplies of the electric power supplying circuit 52 to the front mounting head moving mechanism driving part 45a and the rear mounting head moving mechanism driving part 45b. The second electric power supply interrupting part 54 functions as a second electric power supply interrupting unit which, when a rear carriage connection switch 71b which is a second operating part is operated, only interrupts the electric power supply to the rear mounting head moving mechanism driving part 45b among the electric power supplies of the electric power supplying circuit 52 to the front mounting head moving mechanism driving part 45a and the rear mounting head moving mechanism driving part 45b. The third electric power supply interrupting part 55 functions as a third electric power supply interrupting unit which, when any of a front check door opening and closing switch 72a, a rear check door opening and closing switch 72b, a front emergency stop switch 73a and a rear emergency stop switch 73b which are a third operating part is operated, interrupts both the electric power supply of the electric power supplying circuit 52 to the front mounting head moving mechanism driving part 45a and the electric power supply of the electric power supplying circuit 52 to the rear mounting head moving mechanism driving part 45b.

The front carriage connection switch 71a is provided at the front of the lower part of the base 11 (FIG. 2), and includes a switch which becomes ON when the front carriage 19a is attached to the base 11 (the connector DCa at the side of the front carriage 19a is fitted with the connector KCa at the side of the base 11), and becomes OFF when the front carriage 19a is detached from the base 11 (the connector DCa at the side of the front carriage 19a is pulled out from the connector KCa at the side of the base 11). The rear carriage connection switch 71b is provided at the rear of the lower part of the base 11 (FIG. 2), and includes a switch which becomes ON when the rear carriage 19b is attached to the base 11 (the connector DCb at the side of the rear carriage 19b is fitted with the connector KCb at the side of the base 11), and becomes OFF when the rear carriage 19b is detached from the base 11 (the connector DCb at the side of the rear carriage 19b is pulled out from the connector KCb at the side of the base 11).

The front check door opening and closing switch 72a is provided at the cover member 12 (FIG. 2), and includes a switch which becomes ON by being pressed with a part of the above-mentioned front check door 12a when the front check door 12a is in a closed state relative to the cover member 12, and becomes OFF if the pressing is released when the front check door 12a is in an opened state relative to the cover member 12. The rear check door opening and closing switch 72b is provided at the cover member 12 (FIG. 2), and includes a switch which becomes ON by being pressed with a part of the above-mentioned rear check door 12b when the rear check door 12b is in a closed state relative to the cover member 12, and becomes OFF if the pressing is released when the rear check door 12b is in an opened state relative to the cover member 12.

The front emergency stop switch 73a is provided at the front part of the cover member 12 (FIG. 1) and the rear emergency stop switch 73b is provided at the rear part of the cover member 12 (FIG. 1). When an operator feels that it is necessary to urgently stop the operation of the component mounting device 1, the front emergency stop switch 73a and the rear emergency stop switch 73b are operated by the operator.

The first electric power supply interrupting part 53 includes, for example, to a self-holding type circuit opening and closing switch which uses an electromagnetic relay not shown in the figures. The first electric power supply interrupting part 53 is located at a circuit not interrupting position where the circuit is not interrupted when the front carriage 19a is attached to the base 11 so that the front carriage connection switch 71a becomes ON (FIG. 4), and located at a circuit interrupting position where the circuit is opened when the front carriage 19a is detached from the base 11 so that the front carriage connection switch 71a becomes OFF (FIG. 4).

The second electric power supply interrupting part 54 includes, for example, a self-holding type circuit opening and closing switch which uses an electromagnetic relay not shown in the figures. The second electric power supply interrupting part 54 is located at a circuit not interrupting position where the circuit is not interrupted when the rear carriage 19b is attached to the base 11 so that the rear carriage connection switch 71b becomes ON (FIG. 4), and located at a circuit interrupting position where the circuit is interrupted when the rear carriage 19b is detached from the base 11 so that the rear carriage connection switch 71b becomes OFF (FIG. 4).

The third electric power supply interrupting part 55 includes, for example, a self-holding type circuit opening and closing switch which uses an electromagnetic relay not shown in the figures. The third electric power supply interrupting part 53 is located at a circuit not interrupting position where the circuit is not interrupted when both the front check door 12a and the rear check door 12b are closed so that both the front check door opening and closing switch 72a and the rear check door opening and closing switch 72b become ON (FIG. 4), and located at a circuit interrupting position where the circuit is interrupted when at least one of the front check door 12a and the rear check door 12b is opened so that the front emergency stop switch 73a or the rear emergency stop switch 73b becomes OFF. The third electric power supply interrupting part 55 is located at a circuit interrupting position when the front emergency stop switch 73a or the rear emergency stop switch 73b is operated, even if both the front check door 12a and the rear check door 12b are closed.

When all of the first electric power supply interrupting part 53, the second electric power supply interrupting part 54 and the third power supply interrupting part 55 in the electric power supplying circuit 52 are located at the circuit not interrupting positions, the electric power from the power source 51 is supplied to the front conveyor driving part 41a and the front mounting head moving mechanism driving part 45a so that the component mounting operation can be performed by the front mounting head 16a on the board 2 positioned by the front conveyor 13a (mounting operation of the front operating part), and the electric power from the power source 51 is supplied to the rear conveyor driving part 41b and the rear mounting head moving mechanism driving part 45b so that the component mounting operation can be performed by the rear mounting head 16b on the board 2 positioned by the rear conveyor 13b (mounting operation of the rear operating part). However, when the first electric power supply interrupting part 53 is located at the circuit interrupting position, because the electric power from the power source 51 is not supplied to the front mounting head moving mechanism driving part 45a and the front mounting head 16a cannot be moved, the mounting operation of the front operating part cannot be performed, and when the second electric power supply interrupting part 54 is located at the circuit interrupting position, because the electric power from the power source 51 is not supplied to the rear mounting head moving mechanism driving part 45b and the rear mounting head 16b cannot be moved, the mounting operation of the rear operating part cannot be performed. When the third electric power supply interrupting part 55 is located at the circuit interrupting position, because the electric power from the power source 51 is not supplied to both the front mounting head moving mechanism driving part 45a and rear mounting head moving mechanism driving part 45b, both the mounting operation of the front operating part and the mounting operation of the rear operating part cannot be performed.

Thus, with the component mounting device 1 in the present embodiment, when the front carriage 19a is detached from the base 11, because the front mounting head 16a cannot be moved, even if the hand of the operator is inserted from the part of the base 11 where the front carriage 19a is detached, the safety of the operator in operation is secured. On the other hand, because the movement of the rear mounting head 16b can be continued, the operation efficiency is not reduced.

Likewise, when the rear carriage 19b is detached from the base 11, because the rear mounting head 16b cannot be moved, even if the hand of the operator is inserted from the part of the base 11 where the rear carriage 19b is detached, the safety of the operator in operation is secured. On the other hand, because the movement of the front mounting head 16a can be continued, the operation efficiency is not reduced.

As described above, the component mounting device 1 in the present embodiment includes the electric power supplying circuit 52 which supplies electric power to the front mounting head moving mechanism driving part 45a and the rear mounting head moving mechanism driving part 45b. The electric power supplying circuit 52 has the first electric power supply interrupting part 53 which, when the front carriage connection switch 71a which is the first operating part is operated when the front carriage 19a that is attached to the base 11 is detached from the base 11 (when the first operating part is operated), only interrupts the electric power supply to the front mounting head moving mechanism driving part 45a among the electric power supplies of the electric power supplying circuit 52 to the front mounting head moving mechanism driving part 45a and the rear mounting head moving mechanism driving part 45b, and the second electric power supply interrupting part 54 which, when the rear carriage connection switch 71b which is the second operating part is operated when the rear carriage 19b that is attached to the base 11 is detached from the base 11 (when the second operating part is operated), only interrupts the electric power supply to the rear mounting head moving mechanism driving part 45b among the electric power supplies of the electric power supplying circuit 52 to the front mounting head moving mechanism driving part 45a and the rear mounting head moving mechanism driving part 45b.

Thus, in the component mounting device 1 of the present embodiment, the electric power supplying circuit 52 which supplies electric power to the front mounting head moving mechanism driving part 45a and the rear mounting head moving mechanism driving part 45b has the first electric power supply interrupting part 53 which, when the front carriage connection switch 71a is operated, only interrupts the electric power supply to the front mounting head moving mechanism driving part 45a, and the second electric power supply interrupting part 54 which, when the rear carriage connection switch 71b is operated, only interrupts the electric power supply to the rear mounting head moving mechanism driving part 45b. The front carriage connection switch 71a is operated when one carriage (the front carriage 19a) is detached from the base 11, and the rear carriage connection switch 71b is operated when the other carriage (the rear carriage 19b) is detached from the base 11. When the front carriage 19a is detached from the base 11 in order to change the front parts feeder 14a due to the exhaustion of components or the rear carriage 19b is detached from the base 11 in order to change the rear parts feeder 14b due to the exhaustion of components, the component mounting operation of the conveyor and the mounting head at the side of detaching the carriage is stopped, but the component mounting operation of the conveyor and the mounting head at the other side is continued. Therefore, while the decrease of the operation efficiency is prevented, the safety of the operator can be secured.

In the above embodiment, the first electric power supply interrupting part 53 only interrupts the power supply to the front mounting head moving mechanism driving part 45a when the front carriage connection switch 71a is operated, but it is also possible to interrupt the power supplies to not only the front mounting head moving mechanism driving part 45a but also the front conveyor driving part 41a (even the power supply to other sites associated with the component mounting operation of the front operating part). Likewise, in the above embodiment, the second electric power supply interrupting part 54 only interrupts the power supply to the rear mounting head moving mechanism driving part 45b when the rear carriage connection switch 71b is operated, but it is also possible to interrupt the power supplies to not only the rear mounting head moving mechanism driving part 45b but also the rear conveyor driving part 41b (even the power supply to other sites associated with the component mounting operation of the rear operating part).

In the component mounting device 1 of the present embodiment, the electric power supplying circuit 52 has the third electric power supply interrupting part 55 which are the third electric power supply interrupting unit which, when the front check door 12a or the rear check door 12b which are a part of the cover member 12 which covers the base 11 is opened so that the front check door opening and closing switch 72a or the rear check door opening and closing switch 72b is operated or the front emergency stop switch 73a or the rear emergency stop switch 73b which are the emergency stop operating parts is operated (when the third operating part is operated), interrupts both the electric power supply of the electric power supplying circuit 52 to the front mounting head moving mechanism driving part 45a and the electric power supply of the electric power supplying circuit 52 to the rear mounting head moving mechanism driving part 45b. Thus, when the front check door 12a or the rear check door 12b is opened or the front emergency stop switch 73a or the rear emergency stop switch 73b is operated, the safety of the operator is secured.

In the above-mentioned embodiment, the first operating part is what is operated when the front carriage 19a is detached from the base 11 (the front carriage connection switch 71a), and the second operating part is what is operated when the rear carriage 19b is detached from the base 11 (the rear carriage connection switch 71b), but the first operating part and the second operating part may be what is operated when other requirements are met.

Likewise, the third operating part is what is operated when any one of the front check door opening and closing switch 72a, the rear check door opening and closing switch 72b, the front emergency stop switch 73a and the rear emergency stop switch 73b is operated, but the third operating part may be what is operated when other requirements are met.

This application is based on the Japanese patent application (patent application 2011-001744) filed on Jan. 7, 2011, whose content is incorporated herein by reference.

### INDUSTRIAL APPLICABILITY

A component mounting device is provided so that in the dual lane type component mounting device which performs independent mounting operations, while the decrease of the operation efficiency is prevented, the safety of an operator can be secured.

### DESCRIPTION OF THE SYMBOLS

1 component mounting device
2 board
4 component
11 base
13a front conveyor (first conveyor)
13b rear conveyor (second conveyor)
14a front parts feeder (first parts feeder)
14b rear parts feeder (second parts feeder)
16a front mounting head (first mounting head)
16b rear mounting head (second mounting head)
19a front carriage (first carriage)
19b rear carriage (second carriage)
24a front mounting head moving mechanism (first mounting head moving mechanism)
24b rear mounting head moving mechanism (second mounting head moving mechanism)
45a front mounting head moving mechanism driving part (first mounting head moving mechanism driving part)
45b rear mounting head moving mechanism driving part (second mounting head moving mechanism driving part)
52 electric power supplying circuit
53 first electric power supply interrupting part (first electric power supply interrupting unit)
54 second electric power supply interrupting part (second electric power supply interrupting unit)
55 third electric power supply interrupting part (third electric power supply interrupting part)
71a front carriage connection switch (first operating part)
71b rear carriage connection switch (second operating part)
72a front check door opening and closing switch (third operating part)
72b rear check door opening and closing switch (third operating part)
73a front emergency stop switch (third operating part)
73b rear emergency stop switch (third operating part)

1. A component mounting device, comprising:
a first conveyor and a second conveyor arranged so as to be extended in parallel on a base, and which convey and position boards, respectively;
a first parts feeder attached to the first conveyor side of the base;
a second parts feeder attached to the second conveyor side of the base;
a first mounting head which moves relative to the board positioned by the first conveyor, picks up a component supplied from the first parts feeder and mounts the component on the board positioned by the first conveyor;
a second mounting head which moves relative to the board positioned by the second conveyor, picks up a component supplied from the second parts feeder and mounts the component on the board positioned by the second conveyor;
a first mounting head moving mechanism driving part which drives a first mounting head moving mechanism that is the moving mechanism of the first mounting head;
a second mounting head moving mechanism driving part which drives a second mounting head moving mechanism that is the moving mechanism of the second mounting head; and
an electric power supplying circuit which supplies electric power to the first mounting head moving mechanism driving part and the second mounting head moving mechanism driving part;
wherein the electric power supplying circuit has a first electric power supply interrupting unit which, when a first operating part is operated, only interrupts the electric power supply to the first mounting head moving mechanism driving part among the electric power supplies of the electric power supplying circuit to the first mounting head moving mechanism driving part and the second mounting head moving mechanism driving part, and
a second electric power supply interrupting unit which, when a second operating part is operated, only interrupts the electric power supply to the second mounting head moving mechanism driving part among the electric power supplies of the electric power supplying circuit to the first mounting head moving mechanism driving part and the second mounting head moving mechanism driving part.

2. The component mounting device according to claim 1, wherein:
the first parts feeder is provided on a first carriage attached to the first conveyor side of the base, and the second parts feeder is provided on a second carriage is attached to the second conveyor side of the base; and
the first operating part is operated when the first carriage attached to the base is detached from the base, and the second operating part is operated when the second carriage attached to the base is detached from the base.

3. The component mounting device according to claim 1, wherein:
the electric power supplying circuit has a third electric power supply interrupting unit which, when a third operating part is operated, interrupts both the electric power supply of the electric power supplying circuit to the first mounting head moving mechanism driving part and the electric power supply of the electric power supplying circuit to the second mounting head moving mechanism driving part.

4. The component mounting device according to claim 3, wherein:
the third operating part is operated when a part of a cover member which covers the base is opened or an emergency stop operating part is operated.
